(19) United States
(12) Patent Application Publication
(10) Pub. No.: US 2006/0125041 A1
(43) Pub. Date: Jun. 15, 2006

(54) Transistor using impact ionization and method of manufacturing the same

(75) Inventors: Jong Heon Yang, Daejeon-city (KR); In Bok Baek, Daejeon-city (KR); Ki Ju Im, Daejeon-city (KR); Chang Geun Ahn, Daejeon-city (KR); Won Ju Cho, Daejeon-city (KR); Seong Jae Lee, Daejeon-city (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Electronics and Telecommunications Research Institute

(21) Appl. No.: 11/296,152

(22) Filed: Dec. 6, 2005

(30) Foreign Application Priority Data
Dec. 14, 2004 (KR) 10-2004-0105430
Apr. 25, 2005 (KR) 10-2005-0034030

(51) Int. Cl. H01L 27/095

(52) U.S. Cl. 257/476

(57) ABSTRACT

A transistor using impact ionization and a method of manufacturing the same are provided. A gate dielectric layer, a gate, and first and second spacers are formed on a semiconductor substrate. A first impurity layer is formed spaced from the first spacer and a second impurity layer is formed expanding and overlapping with the second spacer therebelow, by performing slant ion-implantation on the semiconductor substrate using the gate and the first and second spacers as a mask. A source and a drain are formed on the semiconductor substrate to be self-aligned with the first and second spacers, respectively, thereby defining an ionization region between the source and the drain in the semiconductor substrate. The source includes a first silicide layer to form a schottky junction with the ionization region. The drain includes a portion of the second impurity layer overlapping with the second spacer and a second silicide layer which is aligned with the second spacer to form an ohmic contact with the second impurity layer.

### CROSS-REFERENCE TO RELATED PATENT APPLICATIONS

This application claims the benefit of Korean Patent Application Nos. 10-2004-0105430, filed on Dec. 14, 2004, and No. 10-2005-034030, filed on Apr. 25, 2005, in the Korean Intellectual Property Office, the disclosure of which is incorporated herein in its entirety by reference.

### BACKGROUND OF THE INVENTION

1. Field of the Invention

The present invention relates to a semiconductor device, and more particularly, to a transistor controlling a breakdown voltage of a junction using impact ionization and a method of manufacturing the same.

2. Description of the Related Art

With the development of semiconductor technology, needs on high-performance and high-density device have increased. A typical transistor is designed to operate according to the Fermi-Dirac distribution and drift-diffusion of carriers. However, in the operating principle of a metal-oxide semiconductor field effect transistor (MOSFET), it is difficult to lower a subthreshold slope below 60 mV/decade at room temperature. Accordingly, miniaturization of a transistor is limited.

To overcome the limitation on the subthreshold slope, a schottky barrier MOSFET using tunneling instead of diffusion to inject carriers has been proposed. FIG. 1 is a schematic cross-section of a conventional schottky barrier MOSFET. FIGS. 2A through 2C are schematic diagrams for explaining the operating principle of the schottky barrier MOSFET shown in FIG. 1.

Referring to FIG. 1, the schottky barrier MOSFET includes a gate dielectric layer 13 and a gate 14 on a channel region 12 of a substrate 11 and a source 16 and a drain 17 in the substrate 11. Preferably, the source 16 and the drain 17 are formed using silicide produced by reaction between silicon and metal. A spacer 15 may be provided on a sidewall of the gate 14.

The schottky barrier MOSFET was first proposed in 1960s and has been developed in many researches. The cross-section of the schottky barrier MOSFET is very similar to that of a normal MOSFET. However, the source 16 and the drain 17 of the schottky barrier MOSFET are formed using silicide not an impurity doped semiconductor material. Accordingly, a schottky barrier is formed in junction regions between silicon (Si) used as the channel region 12 and each of the source 16 and the drain 17.

Referring to FIG. 2A, when a voltage V_{GS} between the gate 14 and the source 16 and a voltage V_{DS} between the drain 17 and the source 16 are 0 V in the schottky barrier MOSFET shown in FIG. 1, a barrier with a high work function is present between the channel region 12 and the source 16 in the substrate 11 and thus current does not flow in the channel region 12. Here, a barrier qφ_{Bp} against holes is accomplished between the source 16 and the channel region 12.

Referring to FIG. 2B, when the voltage V_{GS} is greater than a threshold voltage V_{T} of the channel region 12 and the voltage V_{DS} is 0 V, although a barrier qφ_{Bn} against electrons is accomplished between the channel region 12 and the source 16, the width of the barrier qφ_{Bn} is thin. Accordingly, electrons can tunnel the barrier qφ_{Bn}.

Referring to FIG. 2C, when the voltage V_{GS} is greater than the threshold voltage V_{T} of the channel region 12 and the voltage V_{DS} is greater than 0 V, the electrons tunneling the barrier qφ_{Bn} between the channel region 12 and the source 16 can flow from the source 16 to the drain 17 across the channel region 12.

As show in FIGS. 1 through 2C, the schottky barrier MOSFET operates by controlling the current flow by controlling the tunneling of carriers through a schottky barrier. Since a tunneling barrier and a gap between the junction of the source 16 or the drain 17 and the channel region 12 exist in the schottky barrier MOSFET, parasitic resistance increases, thereby decreasing operating current.

As another solution to the limitation on the subthreshold slope, an impact ionization MOSFET (I-MOSFET) amplifying operating current using impact ionization has been proposed. FIG. 3 is a schematic cross-section of a conventional I-MOSFET. FIG. 4 is a graph illustrating operational characteristics of a simulation of a conventional I-MOSFET.

Referring to FIG. 3, the I-MOSFET includes a p-i-n diode structure in a silicon layer on a buried oxide layer of a silicon-on-insulator (SOI) substrate 31 and uses an operating principle in which current is amplified by controlling an avalanche breakdown voltage using impact ionization at a junction.

In the operating principle of the I-MOSFET, when a gate voltage supplied to a gate 33 accompanied with a gate dielectric layer 32 is low, a gate length actually extends to an ionization region (I-region) 37 interposed between a source 34 and a drain 35 and thus current does not flow. The I-region 37 includes an overlapping region L_{GATE} overlapping with the gate 33 and a non-overlapping region Lᵢ neighboring the gate 33. When the gate voltage increases, a channel region below the gate 33 is inverted and an actual gate length decreases, thereby inducing a high electric field in the I-region 37. As a result, current flows in the I-region 37 due to avalanche breakdown by impact ionization. Here, the source 34 may be a P⁺-region having a specified thickness tₛᵢ and the drain 35 may be an N⁺-region having the specified thickness tₛᵢ. The gate dielectric layer 32 may have a specified equivalent oxide-layer thickness tₒₓ.

As shown in FIG. 4, it has been reported that the subthreshold slope could be lowered to 5 mV/decade in the I-MOSFET shown in FIG. 3. However, since it is needed to respectively use opposite types of impurities for the source 34 and the drain 35 and to form the I-region 37 having an offset in the conventional I-MOSFET, it is difficult to use self-alignment. To overcome this problem, a device allowing self-alignment has been developed.

FIG. 5 is a schematic cross-section of a vertical I-MOSFET using a sidewall. Referring to FIG. 5, the vertical I-MOSFET using a sidewall includes a step difference on a substrate 51, a gate 53 accompanied with a gate dielectric layer 52 which stands on the substrate 51 along the sidewall, a drain 54, a source 55, an insulating layer 56, and a spacer 57. In such structure, self-alignment is possible. However, leakage current is large due to the bulk substrate 51. In addition, the conventional I-MOSFET using a sidewall is disadvantageous in developing commercial processes and designing a circuit since it has a different structure than normal MOSFETs.

Therefore, a transistor overcoming the problems of the conventional transistors is desired.

### SUMMARY OF THE INVENTION

The present invention provides an impact-ionization transistor, which can overcome the limit of a metal-oxide semiconductor field effect transistor (MOSFET) in miniaturization and allow self-alignment, and a method of manufacturing the same.

According to an aspect of the present invention, there is provided a method of manufacturing a transistor using impact ionization. The method includes forming a gate dielectric layer on a semiconductor substrate; forming a gate on the gate dielectric layer; forming a first spacer and a second spacer on opposite sidewalls, respectively, of the gate; forming a first impurity layer spaced from the first spacer and a second impurity layer expanding to overlap with the second spacer therebelow by performing slant ion-implantation on the semiconductor substrate using the gate and the first and second spacers as a mask; and forming a source and a drain on the semiconductor substrate to be self-aligned with the first and second spacers, respectively, thereby defining an ionization region between the source and the drain in the semiconductor substrate. The source includes a first silicide layer to form a schottky junction with the ionization region, and the drain includes a portion of the second impurity layer overlapping with the second spacer and a second silicide layer which is aligned with the second spacer to form an ohmic contact with the second impurity layer.

According to another aspect of the present invention, there is provided a transistor using impact ionization, including a gate dielectric layer formed on a semiconductor substrate; a gate formed on the gate dielectric layer; a first spacer and a second spacer formed on opposite sidewalls, respectively, of the gate; a source which comprises a first silicide layer on the semiconductor substrate and is self-aligned with the first spacer, the source forming a schottky junction with an ionization region defined as a region of the semiconductor substrate underlying the first spacer and the gate; and a drain comprising an impurity layer, which is formed expanding to a region underlying the second spacer by performing slant ion-implantation on the semiconductor substrate, and a second silicide layer aligned with the second spacer to be in ohmic contact with the impurity layer so that the ionization region is defined between the source and the drain.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic cross-section of a conventional schottky barrier metal-oxide semiconductor field effect transistor (MOSFET);

FIGS. 2A through 2C are energy band diagrams for explaining the operating principle of the schottky barrier MOSFET shown in FIG. 1;

FIG. 3 is a schematic cross-section of a conventional impact-ionization MOSFET (I-MOSFET);

FIG. 4 is a graph illustrating operational characteristics of a simulation of a conventional I-MOSFET;

FIG. 5 is a schematic cross-section of a vertical I-MOSFET using a sidewall;

FIG. 6 is a schematic cross-section of an impact-ionization transistor according to an embodiment of the present invention;

FIG. 7 is an energy band diagram for explaining the operation of the impact-ionization transistor according to the embodiment illustrated in FIG. 6; and

FIGS. 8 through 11 are schematic cross-sections of stages in a method of manufacturing an impact-ionization transistor according to an embodiment of the present invention.

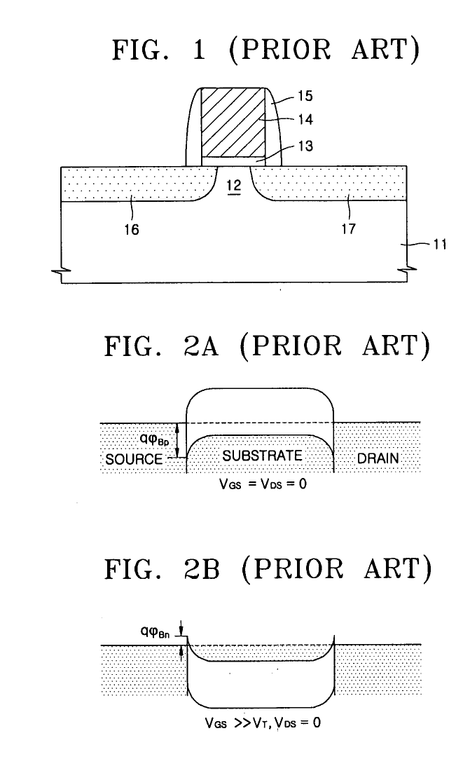

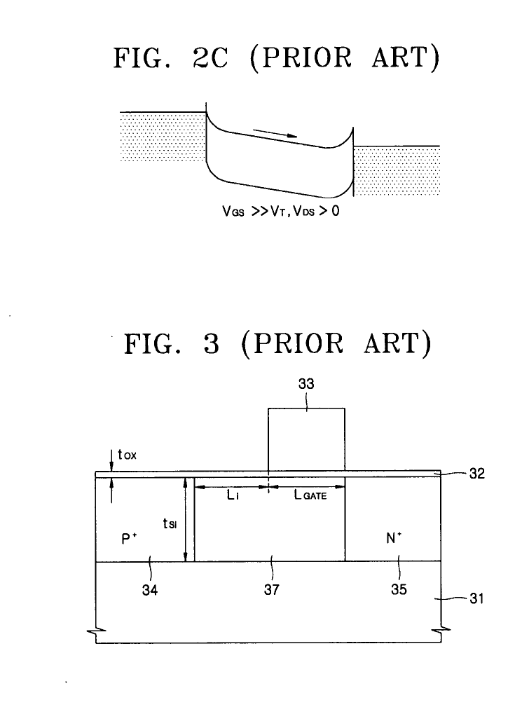

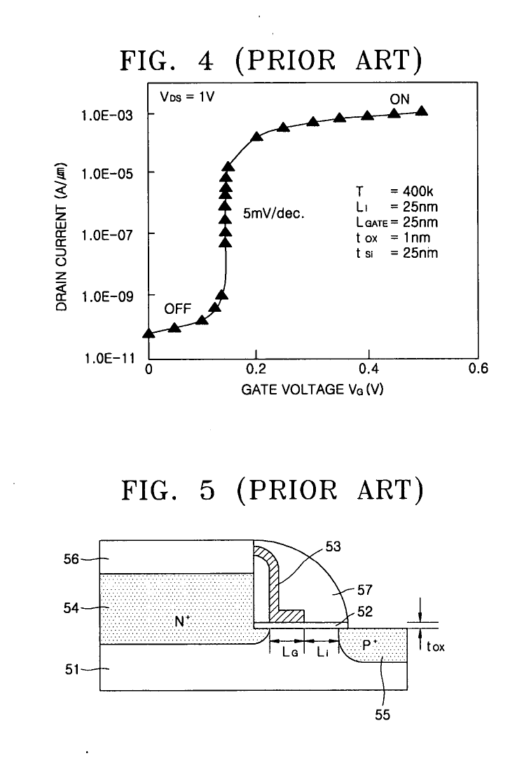

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

In embodiments of the present invention, an impact-ionization transistor including a source with schottky junction and a method of manufacturing the same are provided. An impact-ionization transistor according to an embodiment of the present invention may include a first drain region, i.e., a lightly doped drain (LDD) region facing the source, a second drain region preferably including silicide at the back of the first drain region, an ionization region (I-region) below an offset sidewall spacer adjacent to the source, a gate accompanied with a gate dielectric layer, and a channel region below the gate.

For example, when an N-type impact-ionization metal-oxide semiconductor (I-MOS) transistor is manufactured according to an embodiment of the present invention, a source may be formed using silicide or metal giving a lower barrier against holes than conventional source junction formed by a P⁺ impurity region.

In an embodiment of the present invention, an offset may be given below a sidewall spacer at a source side to secure an I-region between a source formed using silicide and a channel region below a gate. Accordingly, in a transistor according to the embodiment of the present invention, current can be amplified by impact ionization in the I-region due to channel inversion in accordance with a gate voltage. As a result, the transistor according to the embodiment of the present invention can operate as an I-MOS transistor having a smaller subthreshold slope than a conventional transistor. In addition, schottky junction of a source and an LDD structure of a drain can contribute to the reduction of a hot carrier effect (HCE) in the transistor. Since parasitic resistance is reduced, driving current can also be improved. Holes are generated in a channel at a drain side by impact ionization induced by a high electric field and are accumulated in a substrate body. These holes can pass through a low schottky barrier in the junction of the source formed using silicide, thereby reducing the HCE.

According to an embodiment of the present invention, a drain junction may include an LDD region doped with N⁻ impurities using slant ion-implantation before silicide is formed. The LDD region decreases a high electric field in a channel at a drain side, thereby reducing the HCE. The LDD region forms ohmic contact with a suicide layer on its back, thereby reducing parasitic resistance between channels. As a result, driving current is increased.

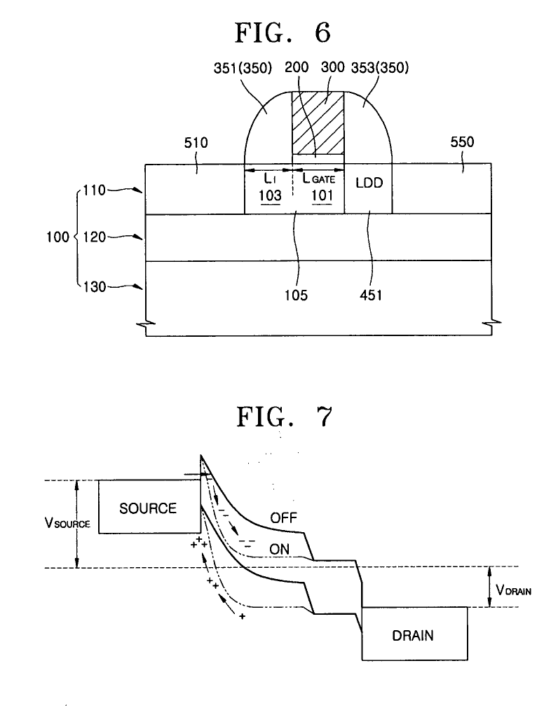

FIG. 6 is a schematic cross-section of an impact-ionization transistor according to an embodiment of the present invention. FIG. 7 is an energy band diagram for explaining the operation of the impact-ionization transistor according to the embodiment illustrated in FIG. 6.

Referring to FIG. 6, the impact-ionization transistor may include a source 510 on a silicon-on-insulator (SOI) substrate 100. The SOI substrate 100 may include a silicon layer 110 as an active region and a bottom oxide layer 120 and a base 130 which underlie the silicon layer 110. The source 510 may be formed using metal or metallic silicide so that a schottky barrier is formed at an interface between the source 510 and the silicon layer 110 of the substrate 100.

In addition, the impact-ionization transistor may include a first drain 451, which is disposed to face the source 510 and may include a semiconductor material region doped with impurities, and a second drain 550 at the back of the first drain 451. The second drain 550 may be formed using metal or metallic silicide.

A gate 300 with a gate dielectric layer 200 is disposed on a portion of the substrate 100, i.e., a channel region between the source 510 and the first drain 451. The gate 300 may be implemented as a metallic gate to prevent a depletion layer from being generated therewithin and to reduce resistance. A gate overlapping region 101 is defined below the gate 300.

A sidewall spacer 350 may be formed using an insulating material on a sidewall of the gate 300. The sidewall spacer 350 includes a first sidewall spacer 351 and a second sidewall spacer 353. The first sidewall spacer 351 on the side of the source 510 is introduced to define a region, which is offset from the gate 300, therebelow. Accordingly, an offset region 103 is defined below the first sidewall spacer 351 to overlap with the first sidewall spacer 351 not with the gate 300 and to be aligned with the first sidewall spacer 351. An I-region 105 is defined as a region between the source 510 and the first drain 451 and includes the gate overlapping region 101 and the offset region 103.

Meanwhile, the first drain 451 may be defined as a region underlying the second sidewall spacer 353. The first drain 451 is a region doped with impurities in the silicon layer 110 and may be implemented as a lightly doped drain (LDD) region. The second drain 550 at the back of the first drain 451 may be formed using metallic suicide. Here, metallic silicide forming the second drain 550 may be selectively disposed only at an exposed portion of the silicon layer 110 adjacent to the second sidewall spacer 353. Accordingly, the second drain 550 is aligned with the second sidewall spacer 353 and the first drain 451 is limited by the second drain 550.

During a process of forming the second drain 550 using metallic silicide, metallic silicide may be disposed at an exposed portion of the silicon layer 110 adjacent to the first sidewall spacer 351. Accordingly, the source 510 includes metallic silicide and is thus aligned with the first sidewall spacer 351.

The silicon layer 110 of the substrate 100 may be formed using pure silicon without being doped with impurities or may be doped with, for example, p-type impurities at a low doping concentration of about 10¹⁵ cm⁻³. Here, the I-region 105, i.e., the channel region between the source 510 and the first drain 451 may be a pure silicon region or a region doped with p-type impurities at a low concentration.

Since the source 510 is formed using metallic silicide, a schottky barrier is formed at an interface between the source 510 and the I-region 105 and particularly the offset region 103. Unlike the source 510, the first drain 451 is implemented as an n⁻-impurity doped region underlying the second sidewall spacer 353. As a result, the source 510 and a drain including the first and second drains 451 and 550 are asymmetric around the gate, 300.

When a negative source voltage V_{source} is supplied to the source 510 of the impact-ionization transistor shown in FIG. 6 and a positive drain voltage V_{drain} is supplied to the first and second drains 451 and 550, an energy band diagram shown in FIG. 7 can be considered.

As shown in FIG. 7, when a gate voltage supplied to the gate 300 (FIG. 6) is such low that a channel of the transistor is turned OFF, electrons in a source cannot tunnel a schottky barrier. Even if a small number of electrons or holes can enter the I-region 105 (FIG. 6), an electric field in the I-region 105 is not high enough to induce impact ionization, and therefore, current does not flow through the channel.

When the gate voltage increases enough to turn ON the channel, the thickness of the schottky barrier of a source becomes thinner and thus electrons are injected into the I-region 105 through quantum mechanical tunneling. Due to a high electric field greater than a threshold voltage in the I-region 105, the injected electrons obtain enough kinetic energy to cause avalanche breakdown through impact ionization. Due to the impact ionization, new electron-hole pairs are generated, electrons are continuously accelerated by the electric field, and holes come down to a valance band and flows toward the source. As a result, current flowing in the channel increases rapidly.

When holes in the channel are also accelerated toward the source by the high electric field, the impact ionization can also be induced. Such multiplication of current occurs rapidly, and therefore, the subthreshold slope of the transistor decreases below 10 mV/decade lower than kT/q. Accordingly, an I-MOS transistor according to the embodiment of the present invention can be effectively used in the field of high-performance and superspeed digital applications.

In conventional 1-MOS transistors, PN junction is used and impact ionization is implemented using minor carriers in the PN junction. However, in the embodiment of the present invention, schottky junction between the I-region 105 and the source 510 is used and impact ionization is implemented using major carriers in the schottky junction.

Consequently, the transistor according to the embodiment of the present invention can realize much amplification of current and low breakdown voltage. Although the embodiment of the present invention needs an additional circuit to supply a large negative voltage to the source 510, a voltage needed to operate the transistor can be decreased since a breakdown voltage can be decreased greatly. Accordingly, the transistor according to the embodiment of the present can remarkably reduce power consumption.

Three methods can be considered to decrease a breakdown voltage of the transistor according to the embodiment of the present.

Firstly, when the concentration of impurities in the I-region 105 is increased, an avalanche breakdown voltage can be effectively decreased. A maximum electric field at the junction is in proportion to a doping concentration \sqrt{Na} of the I-region 105 and the avalanche breakdown voltage is in proportion to 1/Na. When the doping concentration of the I-region 105 is greater than 10¹⁸ cm⁻³, Zener breakdown may occur in the I-region 105 due to tunneling between bands. Accordingly, it is preferable that the doping concentration of the I-region 105 is lower than 10¹⁸ cm⁻³.

Secondly, when the height of a schottky barrier of metallic silicide forming the source 510 is decreased, more electrons is injected into the I-region 105 through quantum mechanical tunneling and thus impact ionization is more accelerated. As a result, a breakdown voltage is decreased.

Thirdly, when the I-region 105 is formed using germanium (Ge) or silicon-germanium (Si_{X}Ge_{1-X}), which has lower band-gap energy than silicon, less kinetic energy is needed to generate electron-hole pairs through impact and thus a breakdown voltage can be decreased. In addition, reducing the thickness of the gate dielectric layer 200 by scaling a device may be helpful in decreasing the breakdown voltage.

Referring back to FIG. 6, an LDD structure is provided on the drain side of the transistor to lower the electric field, thereby reducing an HCE caused by a high electric field. In other words, the first drain 451 may be implemented as an LDD region and the second drain 550 at the back of the first drain 451 may include metal or metallic silicide like the source 510. Such LDD structure reduces a parasitic resistance component caused by a gap between silicide at the back of the LDD structure and the channel. Generally, in a bulk metal-oxide semiconductor field effect transistor (MOSFET) using a bulk silicon substrate or a partially-depleted (PD) SOI MOSFET using a PD SOI substrate, holes generated by the HCE in the drain are accumulated in the substrate and may cause a latch-up effect. However, in the transistor according to the embodiment of the present, holes are not accumulated in the substrate 100 but drain away due to a negative voltage supplied to the source 510.

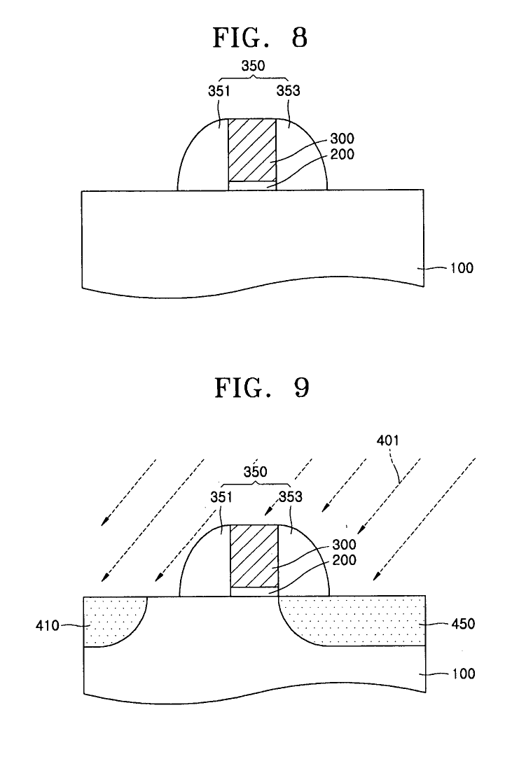

FIGS. 8 through 11 are schematic cross-sections of stages in a method of manufacturing an impact-ionization transistor according to an embodiment of the present invention. Referring to FIG. 8, a gate 300 accompanied with a gate dielectric layer 200 is formed on a substrate 100. The substrate 100 may be a semiconductor substrate, e.g., a silicon substrate, or an SOI substrate as described with reference to FIG. 6. A sidewall spacer 350 including a first sidewall spacer 351 and a second sidewall spacer 353 may be formed using an insulating material on a sidewall of the gate 300 for insulation of a gate channel underlying the gate 300.

A series of processes of forming the gate dielectric layer 200, the gate 300, and the sidewall spacer 350 may be performed in the same manner as manufacturing processes of a general MOSFET. For example, after the gate dielectric layer 200 is formed, a layer for the gate 300 may be formed on the gate dielectric layer 200 and then patterned. Thereafter, a layer for the sidewall spacer 350 may be formed on the patterned structure. Next, anisotropic etching may be performed to form the sidewall spacer 350.

The gate dielectric layer 200 may include a silicon oxide (SiO₂) layer formed by thermally oxidizing silicon. Alternatively, the gate dielectric layer 200 may be formed using a thin film having a high dielectric constant such as a silicon nitride (Si₃N₄) film or a silicon hafnium oxy-nitride (SiHfON) film, which is formed using chemical vapor deposition (CVD).

The gate 300 may be formed using conductive polysilicon but alternatively may be implemented as a metallic gate which can prevent a depletion layer from occurring and provide low gate resistance.

The sidewall spacer 350 may be formed using a material having a low dielectric constant k. For example, the sidewall spacer 350 may be formed including a thin film of an insulating material such as silicon oxide (SiO₂) having a low dielectric constant.

As described with reference to FIG. 6, the width of the sidewall spacer 350 may be determined taking into account conditions that induce impact ionization in the I-region 105. The I-region 105 may be defined as including the gate overlapping region 101 underlying and overlapping with the gate 300 and the offset region 103. Since the gate overlapping region 101 overlaps with the gate 300, the length of the gate overlapping region 101 is determined by a gate length L_{GATE}. A length Lᵢ of the offset region 103, which may be defined as a region underlying and overlapping with the first sidewall spacer 351 that is opposite to the second sidewall spacer 353 and adjacent to the source 501, may be considered as a length of a region where impact ionization occurs actually and may be determined depending on the width of the sidewall spacer 350.

When the size of a device decreases, the thickness of the gate dielectric layer 200, the length of the gate 300, and a gate voltage also decrease. Accordingly, the width of the sidewall spacer 350 can also be decreased. As the width of the sidewall spacer 350 is decreased, the length Lᵢ of the offset region 103 show in FIG. 6 can also be decreased.

Referring to FIG. 9, an asymmetric impurity layer structure including a first impurity layer 410 and a second impurity layer 450 is formed in the semiconductor substrate 100 using slant ion-implantation 401. During the slant ion-implantation 401, the first impurity layer 410 is formed separated from the first sidewall spacer 351 and the second impurity layer 450 is formed under the second sidewall spacer 353 to overlap therewith so that an asymmetric structure is formed around the gate 300.

The slant ion-implantation 401 may be performed by implanting impurity ions in an exposed portion of the semiconductor substrate 100 using the sidewall spacer 350 and the gate 300 as a mask. For example, an asymmetric N⁻-impurity doped structure including the first and second impurity layers 410 and 450 may be formed by implanting ions in a drain (i.e., first and second drains 451 and 550 shown in FIG. 6) at a large angle. Here, a slant angle used in the slang ion-implantation 401 may be about 45° with respect to a surface of the substrate 100 but may be differently set according to the amount of overlapping between the second impurity layer 450 and the second sidewall spacer 353 or the width of the second sidewall spacer 353.

The second impurity layer 450 may be used as the first drain 451 (FIG. 6) which has an LDD structure and extends to overlap with the second sidewall spacer 353. In other words, the first drain 451 including an LDD region on the drain side is formed by implanting impurity ions in a portion of the substrate 100 below the second sidewall spacer 353 and limited by an edge of the gate channel and then performing heat treatment for activation. Since a gate structure acts as a mask on the source side during the slant ion-implantation 401, a portion of the substrate 100 spaced from the gate channel and the first sidewall spacer 351 is doped with impurities, thereby forming the first impurity layer 410. Impurities used in the slant ion-implantation 401 may include phosphorous (P), arsenic (As), and antimony (Sb).

Referring to FIG. 10, silicide layers 510, 530, and 550 are respectively formed on a source region, the gate 300, and a drain region. In detail, a metallic material is deposited on the entire surface of the substrate 100, and then heat treatment is performed to provoke silicidation. As a result, the silicide layers 510, 530, and 550 are formed. Thereafter, a non-silicide portion of the metal material layer is removed using selective wet etching. Therefore, a source including the first silicide layer 510 whose end is aligned with the first sidewall spacer 351 is formed. In addition, the second silicide layer 530 forming a final gate together with conductive polysilicon is formed on the gate 300. The third silicide layer 550 whose end is aligned with the second sidewall spacer 353 is formed to contact the second impurity layer 450 forming the first drain 451, thereby forming a second drain 550 electrically connected to the first drain 451 at the back of the first drain 451.

The source 510 including the first silicide layer 510 has a schottky junction with the offset region 103 underlying the first sidewall spacer 351. The second drain 550 including the third silicide layer 550 accompanies the first drain 451 including the second impurity layer 450 in a form of an LDD structure. Accordingly, the I-region 105 is defined between the source 510 and a drain including the first and second drains 451 and 550 in an asymmetric structure around the gate 300. In other words, the source 510 and the drain (451, 550) are formed in the asymmetric structure.

A metallic material used to form silicide may be erbium, ytterbium, platinum, iridium, cobalt, nickel, or titanium. The height of a tunneling barrier for carrier injection from the source 510 is determined depending on the type of a metallic material. In addition, the breakdown voltage of the transistor also changes according to the height of the tunneling barrier.

For example, when the first drain 451 includes an N⁻-impurity layer and the I-region 105 is a pure semiconductor region or is doped with P-type impurities at a low concentration in an N-channel I-MOS transistor, erbium or ytterbium giving a low height of the schottky barrier against electrons is appropriate for forming the first silicide layer 510 forming the source 510.

When the first drain 451 includes a P⁻-impurity layer and the I-region 105 is a pure semiconductor region or is doped with N-type impurities at a low concentration in a P-channel I-MOS transistor, it may be advantageous to form silicide using platinum or iridium giving a low height of the schottky barrier against holes in decreasing the breakdown voltage. Alternatively, when a schottky barrier is implemented to be used for both of N-type and P-type transistors, it is preferable to use cobalt, nickel, or titanium to form silicide.

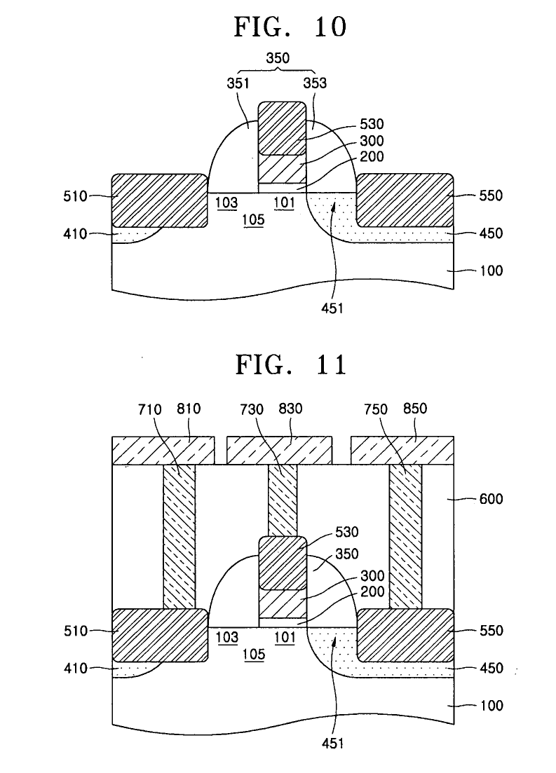

Referring to FIG. 11, an interlayer insulating layer 600 is deposited to cover the source 510, the drain (451, 550), and the gate (300, 530). Here, planarization may be additionally performed on the interlayer insulating layer 600. Thereafter, contacts penetrating the interlayer insulating layer 600, for example, a first contact 710 aligned on and contacting the source 510, a second contact 730 aligned on and contacting the gate (300, 530), and a third contact 750 aligned on and contacting the second drain 550, are formed. Next, a metal wiring process of forming a first wire 810 electrically connected to the first contact 710, a second wire 830 electrically connected to the second contact 730, and a third wire 850 electrically connected to the third contact 750 is performed to complete a device.

A method of manufacturing an impact-ionization transistor according to an embodiment of the present invention can be realized using manufacturing processes of a general MOSFET and allows self-alignment without requiring a separate mask to form the asymmetric p-i-n structure of the I-region 105. Accordingly, it is possible to put an impact-ionization transistor according to an embodiment of the present invention to practical use with application of conventional semiconductor device manufacturing technology.

As described above, the present invention can provide a new impact-ionization transistor and a method of manufacturing the same, which can overcome the limitation of a conventional MOSFET, which controls switching by adjusting the height of a channel barrier, in miniaturizing a device.

According to the present invention, a breakdown voltage of a p-i-n junction structure including a gate is controlled, thereby controlling the flow of current. In addition, conventional MOSFET manufacturing processes can be easily applied to the present invention.

According to the present invention, an I-MOS transistor using impact ionization in a structure having a schottky junction and an asymmetric LDD can be provided. This I-MOS transistor overcomes the limit of a conventional MOSFET that has been developed based on a Moore's law and thus can be used for a super speed and high-performance digital circuit based on a new operating principle. In addition, the present invention is expected to help silicon-based devices, which has led a road map of integrated circuits, to continuously play a leading part afterward.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of manufacturing a transistor using impact ionization, the method comprising:
forming a gate dielectric layer on a semiconductor substrate;
forming a gate on the gate dielectric layer;
forming a first spacer and a second spacer on opposite sidewalls, respectively, of the gate;
forming a first impurity layer spaced from the first spacer and a second impurity layer expanding to overlap with the second spacer therebelow by performing slant ion-implantation on the semiconductor substrate using the gate and the first and second spacers as a mask; and
forming a source and a drain on the semiconductor substrate to be self-aligned with the first and second spacers, respectively, thereby defining an ionization region between the source and the drain in the semiconductor substrate,
wherein the source comprises a first silicide layer to form a schottky junction with the ionization region, and
the drain comprises a portion of the second impurity layer overlapping with the second spacer and a second silicide layer which is aligned with the second spacer to form an ohmic contact with the second impurity layer.

2. The method of claim 1, wherein the semiconductor substrate is formed using one of a silicon substrate and a silicon-on-insulator (SOI) substrate.

3. The method of claim 1, wherein the semiconductor substrate is formed using one of a germanium substrate and a silicon-germanium substrate to decrease an avalanche breakdown voltage.

4. The method of claim 1, wherein the ionization region is one of a pure silicon region and a region doped with impurities having a conductivity type opposite to that of the second impurity layer at a concentration of less than 10¹⁶ cm⁻³.

5. The method of claim 1, wherein the gate dielectric layer comprises one selected from the group consisting of a silicon oxide (SiO₂) layer formed using thermal oxidization, and a silicon nitride (Si₃N₄) film and a silicon hafnium oxy-nitride (SiHfON) film which are formed using chemical vapor deposition (CVD).

6. The method of claim 1, wherein the first and second suicide layers are formed by forming a metal layer covering the semiconductor layer including the gate, silicidating the metal layer, and selectively removing a portion of the metal layer that has not been silicidated.

7. The method of claim 6, wherein the metal layer comprises one selected from the group consisting of erbium, ytterbium, platinum, iridium, cobalt, nickel, and titanium.

8. A transistor using impact ionization, comprising:
a gate dielectric layer formed on a semiconductor substrate;
a gate formed on the gate dielectric layer;
a first spacer and a second spacer formed on opposite sidewalls, respectively, of the gate;
a source which comprises a first silicide layer on the semiconductor substrate and is self-aligned with the first spacer, the source forming a schottky junction with an ionization region defined as a region of the semiconductor substrate underlying the first spacer and the gate; and
a drain comprising an impurity layer, which is formed expanding to a region underlying the second spacer by performing slant ion-implantation on the semiconductor substrate, and a second silicide layer aligned with the second spacer to be in ohmic contact with the impurity layer so that the ionization region is defined between the source and the drain.

9. The transistor of claim 8, wherein one of the first and second silicide layer is formed by selectively silicidating a metal layer comprising one selected from the group consisting of erbium, ytterbium, platinum, iridium, cobalt, nickel, and titanium.

10. The transistor of claim 8, wherein the semiconductor substrate is formed using one of a silicon substrate and a silicon-on-insulator (SOI) substrate.

11. The transistor of claim 8, wherein the semiconductor substrate is formed using one of a germanium substrate and a silicon-germanium substrate to decrease an avalanche breakdown voltage.

12. The transistor of claim 8, wherein the ionization region is one of a pure silicon region and a region doped with impurities having a conductivity type opposite to that of the impurity layer at a concentration of less than 10¹⁶ cm⁻³.

13. The transistor of claim 8, wherein the gate dielectric layer comprises one selected from the group consisting of a silicon oxide (SiO₂) layer formed using thermal oxidization, and a silicon nitride (Si₃N₄) film and a silicon hafnium oxy-nitride (SiHfON) film which are formed using chemical vapor deposition (CVD).
